(19) United States
(12) Patent Application Publication
(10) Pub. No.: US 2026/0164966 A1
(43) Pub. Date: Jun. 11, 2026

(54) DISPLAY DEVICE AND ELECTRONIC DEVICE INCLUDING THE SAME

(71) Applicant: Samsung Display Co., Ltd., Yongin-si (KR)

(72) Inventor: SUNGSIK YUN, Yongin-si (KR)

(21) Appl. No.: 19/246,274

(22) Filed: Jun. 23, 2025

(30) Foreign Application Priority Data
Dec. 9, 2024 (KR) 10-2024-0181763

(51) Int. Cl. H10K 59/131; H10K 59/40

(52) U.S. Cl. CPC H10K 59/131; H10K 59/40

(57) ABSTRACT

A display device includes a substrate including a display area, and a non-display area adjacent to the display area, a light-emitting element in the display area above the substrate, output pads in the non-display area above the substrate, input pads in the non-display area above the substrate, and spaced apart from the output pads in a plan view, a first groove adjacent to the output pads, and a driving chip bonded to the output pads and the input pads.

### CROSS-REFERENCE TO RELATED APPLICATION

The present application claims priority to, and the benefit of, Korean Patent Application No. 10-2024-0181763, filed on Dec. 9, 2024, in the Korean Intellectual Property Office, the entire disclosure of which is incorporated herein by reference.

### BACKGROUND

### 1. Field

The present disclosure relates to a display device for providing visual information and an electronic device including the same.

### 2. Description of the Related Art

A display device is a device that displays an image for providing visual information to a user. Among display devices, an organic light-emitting display device has recently attracted attention.

The display device may include pixels, input pads, and output pads. Each of the pixels may emit light. Each of the input pads and the output pads may be bonded to a driving chip. Accordingly, the driving chip may provide a signal to the pixels through the input pads and the output pads.

### SUMMARY

Embodiments of the present disclosure provide a display device in which generation and propagation of cracks are suppressed.

Embodiments of the present disclosure provide an electronic device including the display device.

A display device according to one or more embodiments includes a substrate including a display area, and a non-display area adjacent to the display area, a light-emitting element in the display area above the substrate, output pads in the non-display area above the substrate, input pads in the non-display area above the substrate, and spaced apart from the output pads in a plan view, a first groove adjacent to the output pads, and a driving chip bonded to the output pads and the input pads.

The first groove may be adjacent to ones of the output pads at an outermost position among the output pads.

The ones of the output pads at the outermost position may include stacked conductive patterns, wherein the first groove accommodates some of the conductive patterns.

The ones of the output pads at the outermost position may include a first conductive pattern, a second conductive pattern above the first conductive pattern, a third conductive pattern above the second conductive pattern, and a fourth conductive pattern above the third conductive pattern, wherein the first groove accommodates at least a portion of the fourth conductive pattern.

The first groove may be spaced apart from the third conductive pattern in a plan view.

The display device may further include a first touch electrode above the light-emitting element, and a second touch electrode above the first touch electrode, wherein the fourth conductive pattern and the second touch electrode are in a same layer.

The output pads may be in a first row, in a second row, and in a third row, wherein the first groove is adjacent to ones of the output pads in the first row.

The display device may further include a second groove adjacent to others of the output pads in the third row.

The others of the output pads in the third row may include stacked conductive patterns, wherein the second groove accommodates some of the conductive patterns.

The others of the output pads in the third row may include a first conductive pattern, a second conductive pattern above the first conductive pattern, a third conductive pattern above the second conductive pattern, and a fourth conductive pattern above the third conductive pattern, wherein the second groove accommodates at least a portion of the fourth conductive pattern, and is spaced apart from the third conductive pattern in a plan view.

The display device may further include a third groove adjacent to the input pads, the input pads including stacked conductive patterns, wherein the third groove accommodates some of the conductive patterns.

The first groove may be repeatedly arranged in an island shape.

A display device according to one or more embodiments includes a substrate including a display area, and a non-display area adjacent to the display area, a light-emitting element in the display area above the substrate, output pads in the non-display area above the substrate, input pads in the non-display area above the substrate, and spaced apart from the output pads in a plan view, a first groove adjacent to the input pads, and a driving chip bonded to the output pads and the input pads.

The input pads may include stacked conductive patterns, wherein the first groove accommodates some of the conductive patterns.

The input pads may include a first conductive pattern, a second conductive pattern above the first conductive pattern, a third conductive pattern above the second conductive pattern, and a fourth conductive pattern above the third conductive pattern, wherein the first groove accommodates at least a portion of the fourth conductive pattern.

The first groove may be spaced apart from the third conductive pattern in a plan view.

The display device may further include a first touch electrode above the light-emitting element, and a second touch electrode above the first touch electrode, wherein the fourth conductive pattern and the second touch electrode are in a same layer.

An electronic device according to one or more embodiments includes a substrate including a display area, and a non-display area adjacent to the display area, a light-emitting element in the display area above the substrate, output pads in the non-display area above the substrate, input pads in the non-display area above the substrate, and spaced apart from the output pads in a plan view, a first groove adjacent to the output pads, a driving chip bonded to the output pads and the input pads, and a memory device configured to store data information.

The first groove may be adjacent to ones of the output pads at an outermost position among the output pads.

The ones of the output pads at the outermost position may include stacked conductive patterns, wherein the first groove accommodates some of the conductive patterns.

Accordingly, when the driving chip is bonded on the substrate, generation and propagation of cracks may be reduced or prevented around the first groove.

### BRIEF DESCRIPTION OF THE DRAWINGS

Illustrative, non-limiting embodiments will be more clearly understood from the following detailed description in conjunction with the accompanying drawings.

FIG. 1 is a plan view illustrating a display device according to embodiments.

FIG. 2 is an enlarged plan view illustrating an example of area A of FIG. 1.

FIG. 3 is a cross-sectional view taken along the line I-I′ of the display device of FIG. 2.

FIG. 4 is a cross-sectional view taken along the line II-II′ of the display device of FIG. 2.

FIG. 5 is an enlarged cross-sectional view illustrating an example of area B of FIG. 3.

FIG. 6 is a cross-sectional view illustrating a pixel included in the display device of FIG. 1.

FIG. 7 is an enlarged cross-sectional view illustrating an example of area B of FIG. 3.

FIG. 8 is an enlarged plan view illustrating an example of area A of FIG. 1.

FIG. 9 is an enlarged plan view illustrating an example of area A of FIG. 1.

FIG. 10 is a block diagram illustrating an electronic device according to embodiments.

FIG. 11 is a diagram illustrating an example in which the electronic device of

FIG. 10 is implemented as a smartphone.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure.

A person of ordinary skill in the art would appreciate, in view of the present disclosure in its entirety, that each suitable feature of the various embodiments of the present disclosure may be combined or combined with each other, partially or entirely, and may be technically interlocked and operated in various suitable ways, and each embodiment may be implemented independently of each other or in conjunction with each other in any suitable manner unless otherwise stated or implied.

In the drawings, the relative sizes of elements, layers, and regions may be exaggerated for clarity and/or descriptive purposes. In other words, because the sizes and thicknesses of elements in the drawings are arbitrarily illustrated for convenience of description, the disclosure is not limited thereto. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “over,” “higher,” “upper side,” “side” (e.g., as in “sidewall”), and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a plan view” means when an object portion is viewed from above, and the phrase “in a schematic cross-sectional view” means when a schematic cross-section taken by vertically cutting an object portion is viewed from the side. The terms “overlap” or “overlapped” mean that a first object may be above or below or to a side of a second object, and vice versa. Additionally, the term “overlap” may include stack, face or facing, extending over, covering, or partly covering or any other suitable term as would be appreciated and understood by those of ordinary skill in the art. The expression “not overlap” may include meaning, such as “apart from” or “set aside from” or “offset from” and any other suitable equivalents as would be appreciated and understood by those of ordinary skill in the art. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component (e.g., an apparatus, a device, a circuit, a wire, an electrode, a terminal, a conductive film, etc.) is referred to as being “formed on,” “on,” “connected to,” or “(operatively, functionally, or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a transistor, a resistor, an inductor, a capacitor, a diode and/or the like. Accordingly, a connection is not limited to the connections illustrated in the drawings or the detailed description and may also include other types of connections. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XY, YZ, and XZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list. When “C to D” is stated, it means C or more and D or less, unless otherwise specified.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

As used herein, the terms “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5 % of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.” Furthermore, the expression “being the same” may mean “being substantially the same”. In other words, the expression “being the same” may include a range that can be tolerated by those of ordinary skill in the art. The other expressions may also be expressions from which “substantially” has been omitted.

In some embodiments well-known structures and devices may be described in the accompanying drawings in relation to one or more functional blocks (e.g., block diagrams), units, and/or modules to avoid unnecessarily obscuring various embodiments. Those skilled in the art will understand that such block, unit, and/or module are/is physically implemented by a logic circuit, an individual component, a microprocessor, a hard wire circuit, a memory element, a line connection, and other electronic circuits. This may be formed using a semiconductor-based manufacturing technique or other manufacturing techniques. The block, unit, and/or module implemented by a microprocessor or other similar hardware may be programmed and controlled using software to perform various functions discussed herein, optionally may be driven by firmware and/or software. In addition, each block, unit, and/or module may be implemented by dedicated hardware, or a combination of dedicated hardware that performs some functions and a processor (for example, one or more programmed microprocessors and related circuits) that performs a function different from those of the dedicated hardware. In addition, in some embodiments, the block, unit, and/or module may be physically separated into two or more interact individual blocks, units, and/or modules without departing from the scope of the present disclosure. In addition, in some embodiments, the block, unit and/or module may be physically combined into more complex blocks, units, and/or modules without departing from the scope of the present disclosure.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

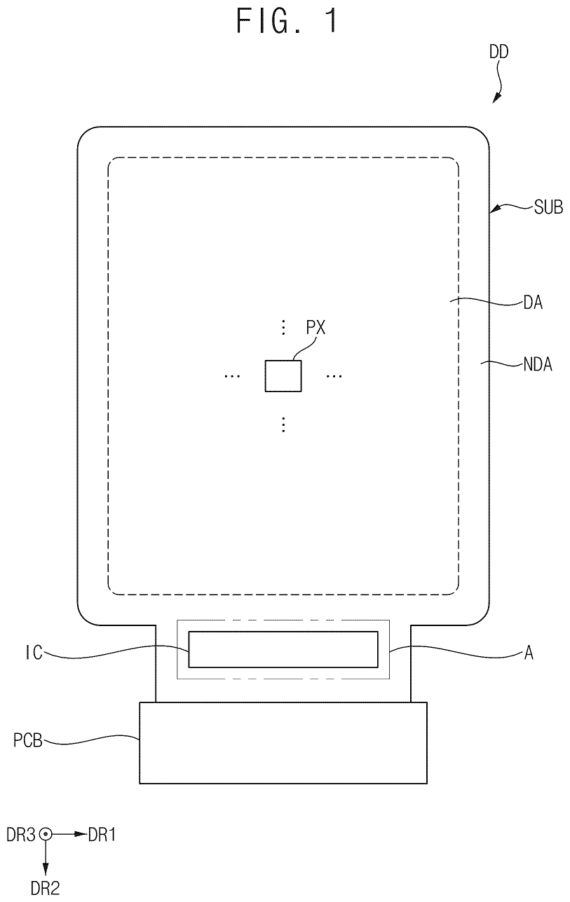

FIG. 1 is a plan view illustrating a display device according to embodiments.

Referring to FIG. 1, a display device DD according to embodiments may include a substrate SUB, a driving chip IC, and a circuit board PCB.

The substrate SUB may include a display area DA and a non-display area NDA. The display area DA may be defined as an area for emitting light. The non-display area NDA may be defined as an area in which there are components for transmitting signals to the display area DA.

Pixels PX may be located on the substrate SUB. The pixels PX may be located in the display area DA. Each of the pixels PX may emit light based on a signal applied from the non-display area NDA. The pixels PX may be repeatedly located in the display area DA along a first direction DR1, and along a second direction DR2 crossing the first direction DR1. Accordingly, the display area DA may emit light in an entirety of a corresponding area.

The non-display area NDA may be adjacent to the display area. For example, the non-display area NDA may contact the display area DA. For example, the non-display area NDA may be located around the display area DA (e.g., in plan view). In one or more embodiments, the non-display area NDA may surround at least a portion of the display area DA. For example, the non-display area NDA may entirely surround the display area DA (e.g., in plan view), but this discourse is not necessarily limited thereto. Drivers for driving the pixels PX may be located in the non-display area NDA. For example, a gate driver, a light-emitting driver, a power voltage generator, and/or the like, may be located in the non-display area NDA.

The driving chip IC may be located (or bonded) on the substrate SUB (as used herein, “located on” may mean “above”). The driving chip IC may be located in the non-display area NDA. The driving chip IC may be spaced apart from the display area DA in a plan view. For example, the driving chip IC may be spaced apart from the display area DA in the second direction DR2, but this disclosure is not necessarily thereto. The driving chip IC may convert a digital signal among driving signals into an analog data signal. The driving chip IC may provide the analog data signal to the pixels PX. In one or more embodiments, the number of the driving chip IC may be one. However, this disclosure is not necessarily thereto, and the number of the driving chip IC may vary depending on embodiments. For example, the number of the driving chip IC may be two or more.

The circuit board PCB may be located (or bonded) on the substrate SUB. For example, the circuit board PCB may be located (or bonded) on one end of the substrate SUB. The circuit board PCB may be located in the non-display area NDA. The circuit board PCB may be spaced apart from the driving chip IC in a plan view. For example, the circuit board PCB may be spaced apart from the driving chip IC in the second direction DR2, but this disclosure is not necessarily thereto. The circuit board PCB may provide driving signals, driving voltages, and/or the like to the driving chip IC and the pixels PX. In one or more embodiments, the number of the circuit board PCB may be one. However, this disclosure is not necessarily thereto, and the number of the circuit board PCB may vary depending on embodiments. For example, the number of the circuit board PCB may be two or more.

In one or more embodiments, the first direction DR1 and the second direction DR2 crossing the first direction DR1 may be defined. For example, the second direction DR2 may be substantially perpendicular to the first direction DR1. However, this disclosure is not limited thereto, and the second direction DR2 may form an acute angle or an obtuse angle with the first direction DR1. In addition, a third direction DR3 crossing a plane formed by the first direction DR1 and the second direction DR2 may be defined. For example, the third direction DR3 may be substantially perpendicular to the plane formed by the first direction DR1 and the second directions DR2. However, this disclosure is not limited thereto, and the third direction DR3 may form an acute angle or an obtuse angle with the plane formed by the first direction DR1 and the second direction DR2.

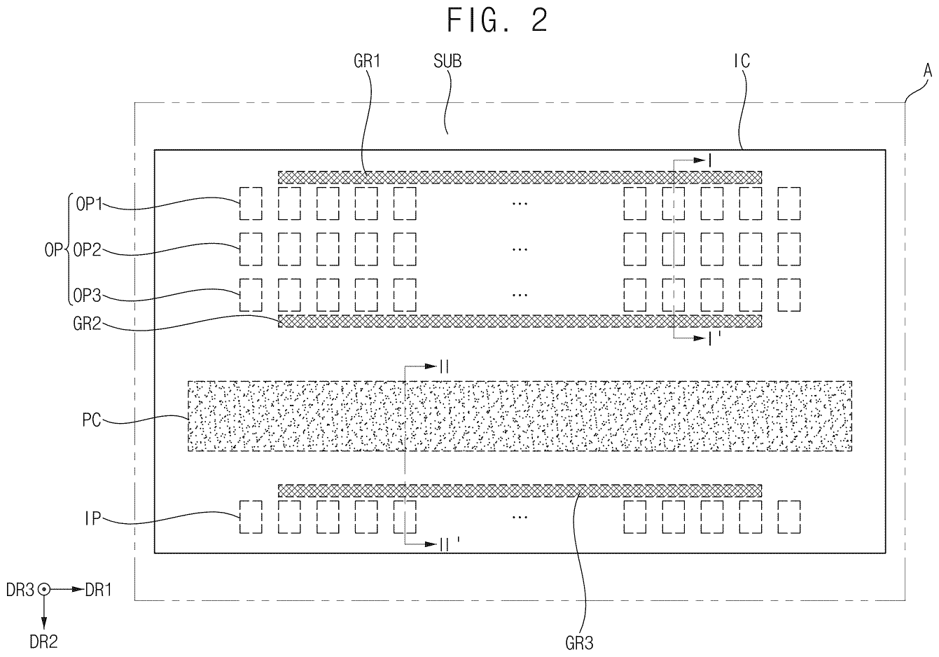

FIG. 2 is an enlarged plan view illustrating an example of area A of FIG. 1.

Referring to FIG. 2, output pads OP, input pads IP, and a test circuit portion PC may be located on the substrate SUB. The output pads OP, the input pads IP, and the test circuit portion PC may be located in the non-display area NDA. The output pads OP, the input pads IP, and the test circuit portion PC may overlap the driving chip IC in a plan view.

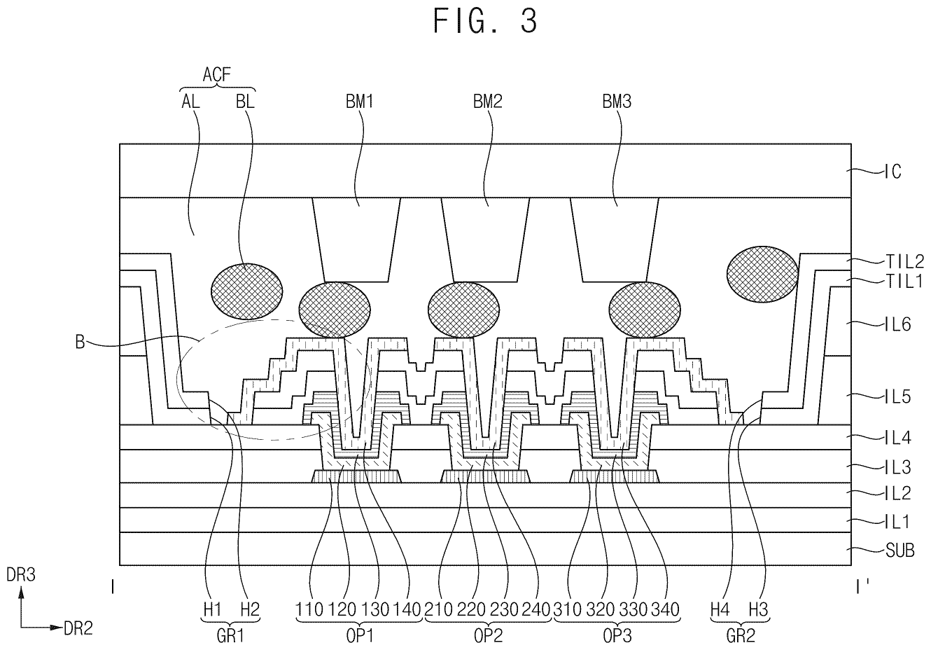

The driving chip IC may be bonded to the output pads OP. For example, the driving chip IC may be bonded to the output pads OP through a conductive film (e.g., a conductive film ACF of FIG. 3). The output pads OP may be repeatedly located along the first direction DR1 and the second direction DR2. In one or more embodiments, the output pads OP may be arranged in three rows and n columns, where n is a natural number. For example, the output pads OP may include first output pads OP1 located in a first row, second output pads OP2 located in a second row, and third output pads OP3 located in a third row. In this case, among the output pads OP, the output pads located at outermost positions with respect to the second direction DR2 may be the first output pads OP1 and the third output pads OP3.

However, this disclosure is not necessarily thereto, and in one or more embodiments, the output pads OP may be arranged in two rows and n columns, where n is a natural number. In this case, among the output pads OP, the output pads located at outermost positions with respect to the second direction DR2 may be the output pads located in a first row and the output pads located in a second row.

In one or more embodiments, the output pads OP may be arranged in one row and n columns, where n is a natural number. In this case, among the output pads OP, the output pads located at outermost positions in the second direction DR2 may be the output pads located in a first row.

In one or more embodiments, the output pads OP may be arranged in m rows, where m is a natural number greater than three, and n columns, where n is a natural number. In this case, among the output pads OP, the output pads located at outermost positions in the second direction DR2 may be the output pads located in a first row and the output pads located in an m-th row.

In summary, the output pads OP may be arranged in m rows, where m is a natural number, and n columns, where n is a natural number, and in this case, among the output pads OP, the output pads located at outermost positions in the second direction DR2 may be the output pads located in a first row and the output pads located in an m-th row.

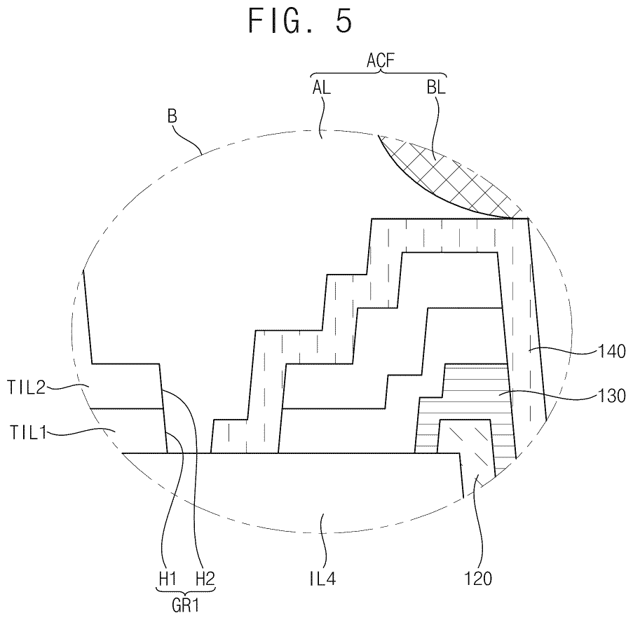

The driving chip IC may be bonded to the input pads IP. For example, the driving chip IC may be bonded to the input pads IP through a conductive film (e.g., a conductive film ACF of FIG. 5). The input pads IP may be spaced apart from the output pads OP in a plan view. For example, the input pads IP may be spaced apart from the output pads OP in the second direction DR2. In one or more embodiments, the input pads IP may be arranged in one row and n columns, where n is a natural number. For example, the input pads IP may be repeatedly located along the first direction DR1. However, this disclosure is not necessarily thereto, and in one or more embodiments, the input pads IP may also be arranged in m rows, where m is a natural number greater than one, and n columns, where n is a natural number. For example, the input pads IP may be arranged in two rows and n columns, where n is a natural number.

The test circuit portion PC may be located between the output pads OP and the input pads IP in a plan view. For example, the test circuit portion PC may be located between the output pads OP located at outermost positions in the second direction DR2 and the input pads IP in a plan view. For example, the test circuit portion PC may be located between the third output pads OP3 and the input pads IP in a plan view. The test circuit portion PC may provide a signal for testing an operating state of the display device (e.g., the display device DD of FIG. 1) to the display area (e.g., the display area DA of FIG. 1) before final product shipment. Although not illustrated in FIG. 2, the display device may further include test lines that connect the test circuit portion PC and some of the output pads OP. The test circuit portion PC may provide the signal for testing an operating state of the display device to the display area through the test lines and the some of the output pads OP.

In one or more embodiments, the display device may include a first groove GR1, a second groove GR2, and a third groove GR3. Each of the first groove GR1, the second groove GR2, and the third groove GR3 may be located in the non-display area NDA. Each of the first groove GR1, the second groove GR2, and the third groove GR3 may at least partially overlap the driving chip IC in a plan view.

In one or more embodiments, the first groove GR1 may be located adjacent to the output pads OP. In one or more embodiments, the first groove GR1 may be located adjacent to the output pads located at outermost positions in the second direction DR2 among the output pads OP. For example, as illustrated in FIG. 2, the first groove GR1 may be located adjacent to the first output pads OP1. In one or more embodiments, the first groove GR1 may extend in the first direction DR1. The first groove GR1 may overlap, or may be aligned with, some of the output pads OP in the second direction DR2, and may not overlap other output pads OP in the second direction DR2 (e.g., may be offset the other output pads with respect to the first direction DR1). For example, as illustrated in FIG. 2, the first groove GR1 may not overlap, in the second direction DR2, the output pads located in a first column and the output pads located in an n-th column among the output pads OP arranged in three rows and n columns, where n is a natural number (e.g., while overlapping the output pads in the other columns).

In one or more embodiments, the second groove GR2 may be located adjacent to the output pads OP. In one or more embodiments, the second groove GR2 may be located adjacent to the output pads located at outermost positions in the second direction DR2 among the output pads OP. For example, as illustrated in FIG. 2, the second groove GR2 may be located adjacent to the third output pads OP3. As described above, the output pads OP may be arranged in m rows, where m is a natural number, and n columns, where n is a natural number, and in this case, the second groove GR2 may be located adjacent to the output pads located in an m-th row. In one or more embodiments, the second groove GR2 may extend in the first direction DR1. The second groove GR2 may overlap some of the output pads OP in the second direction DR2 (e.g., may be aligned with some of the output pads in the second direction DR2), and may not overlap other output pads OP in the second direction DR2 (e.g., may be offset from the other output pads OP in the first direction DR1 and the second direction DR2). For example, as illustrated in FIG. 2, the second groove GR2 may not overlap, in the second direction DR2, the output pads located in a first column and the output pads located in an n-th column among the output pads OP arranged in three rows and n columns, where n is a natural number.

In one or more embodiments, the third groove GR3 may be located adjacent to the input pads IP. In one or more embodiments, the third groove GR3 may extend in the first direction DR1. The third groove GR3 may overlap some of the input pads IP in the second direction DR2, and may not overlap other input pads IP in the second direction DR2. For example, as illustrated in FIG. 2, the third groove GR3 may not overlap, in the second direction DR2, the input pads located in a first column and the input pads located in an n-th column among the input pads IP.

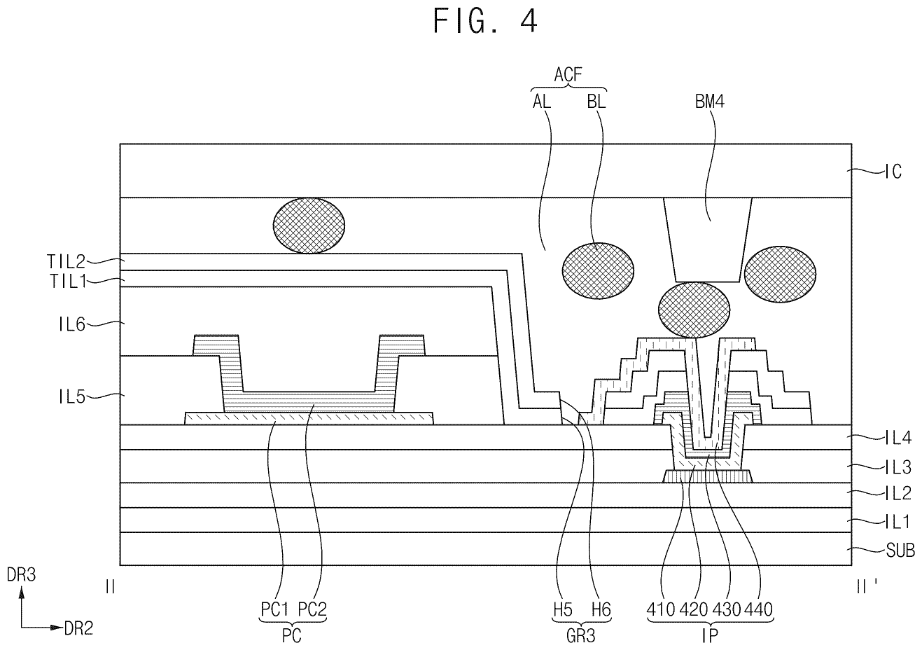

FIG. 3 is a cross-sectional view taken along the line I-I′ of the display device of FIG. 2. FIG. 4 is a cross-sectional view taken along the line II-II′ of the display device of FIG. 2.

Referring to FIGS. 3 and 4, the display device (e.g., the display device DD of FIG. 1) according to embodiments of this disclosure may include a substrate SUB, a first insulating layer IL1, a second insulating layer IL2, a third insulating layer IL3, a fourth insulating layer IL4, a fifth insulating layer IL5, a sixth insulating layer IL6, a first touch-insulating layer TIL1, a second touch-insulating layer TIL2, a first bump electrode BM1, a second bump electrode BM2, a third bump electrode BM3, a fourth bump electrode BM4, a conductive film ACF, the first groove GR1, the second groove GR2, the third groove GR3, the first output pad OP1, the second output pad OP2, the third output pad OP3, the input pad IP, the test circuit portion PC, and the driving chip IC.

The substrate SUB may be a base of the display device. The substrate SUB may include a transparent material or an opaque material. The substrate SUB may be formed of a transparent resin substrate. Example of the transparent resin substrate may include a polyimide substrate. In this case, the polyimide substrate may include a first organic layer, a first barrier layer, a second organic layer, and/or the like. Optionally, the substrate SUB may include a quartz substrate (e.g. a synthetic quartz substrate, a fluorine-doped quartz substrate), a calcium fluoride substrate, a sodalime glass substrate, a non-alkali glass substrate, and/or the like. These materials may be used alone or in combination with each other.

The first insulating layer IL1 may be located on the substrate SUB. The first insulating layer IL1 may include inorganic materials, such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The second insulating layer IL2 may be located on the first insulating layer IL1. The second insulating layer IL2 may include inorganic materials, such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

A first conductive pattern 110 of the first output pad OP1, a first conductive pattern 210 of the second output pad OP2, a first conductive pattern 310 of the third output pad OP3, and a first conductive pattern 410 of the input pad IP may be located on the second insulating layer IL2. The first conductive patterns 110, 210, 310, and 410 may be spaced apart from each other in a plan view.

The third insulating layer IL3 may be located on the second insulating layer IL2. The third insulating layer IL3 may cover the first conductive patterns 110, 210, 310, and 410. The third insulating layer IL3 may define a first opening, a second opening, a third opening, and a fourth opening. The first opening may expose at least a portion of an upper surface of the first conductive pattern 110. The second opening may expose at least a portion of an upper surface of the first conductive pattern 210. The third opening may expose at least a portion of an upper surface of the first conductive pattern 310. The fourth opening may expose at least a portion of an upper surface of the first conductive pattern 410. The third insulating layer IL3 may include an inorganic material, such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The fourth insulating layer IL4 may be located on the third insulating layer IL3. The fourth insulating layer IL4 may define a fifth opening, a sixth opening, a seventh opening, and an eighth opening. The fifth opening may overlap the first opening in a plan view. For example, the first opening and the fifth opening may communicate with each other to form a first through-hole. The sixth opening may overlap the second opening in a plan view. For example, the second opening and the sixth opening may communicate with each other to form a second through-hole. The seventh opening may overlap the third opening in a plan view. For example, the third opening and the seventh opening may communicate with each other to form a third through-hole. The eighth opening may overlap the fourth opening in a plan view. For example, the fourth opening and the eighth opening may communicate with each other to form a fourth through-hole. The fourth insulating layer IL4 may include an inorganic material, such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

A second conductive pattern 120 may be located on the first conductive pattern 110. The second conductive pattern 120 may fill at least a portion of the first through-hole. The second conductive pattern 120 may contact the upper surface of the first conductive pattern 110. A third conductive pattern 130 may be located on the second conductive pattern 120. The third conductive pattern 130 may fill at least a portion of the first through-hole. The third conductive pattern 130 may contact an upper surface of the second conductive pattern 120. A fourth conductive pattern 140 may be located on the third conductive pattern 130. The fourth conductive pattern 140 may fill at least a portion of the first through-hole. The fourth conductive pattern 140 may contact an upper surface of the third conductive pattern 130. The first output pad OP1 may include the first conductive pattern 110, the second conductive pattern 120, the third conductive pattern 130, and the fourth conductive pattern 140. For example, the first output pad OP1 may be a portion in which the first conductive pattern 110, the second conductive pattern 120, the third conductive pattern 130, and the fourth conductive pattern 140 overlap each other in a plan view.

A second conductive pattern 220 may be located on the first conductive pattern 210. The second conductive pattern 220 may fill at least a portion of the second through-hole. The second conductive pattern 220 may contact the upper surface of the first conductive pattern 210. A third conductive pattern 230 may be located on the second conductive pattern 220. The third conductive pattern 230 may fill at least a portion of the second through-hole. The third conductive pattern 230 may contact an upper surface of the second conductive pattern 220. A fourth conductive pattern 240 may be located on the third conductive pattern 230. The fourth conductive pattern 240 may fill at least a portion of the second through-hole. The fourth conductive pattern 240 may contact an upper surface of the third conductive pattern 230. The second output pad OP2 may include the first conductive pattern 210, the second conductive pattern 220, the third conductive pattern 230, and the fourth conductive pattern 240. For example, the second output pad OP2 may be a portion in which the first conductive pattern 210, the second conductive pattern 220, the third conductive pattern 230, and the fourth conductive pattern 240 overlap each other in a plan view.

A second conductive pattern 320 may be located on the first conductive pattern 310. The second conductive pattern 320 may fill at least a portion of the third through-hole. The second conductive pattern 320 may contact the upper surface of the first conductive pattern 310. A third conductive pattern 330 may be located on the second conductive pattern 320. The third conductive pattern 330 may fill at least a portion of the third through-hole. The third conductive pattern 330 may contact an upper surface of the second conductive pattern 320. A fourth conductive pattern 340 may be located on the third conductive pattern 330. The fourth conductive pattern 340 may fill at least a portion of the third through-hole. The fourth conductive pattern 340 may contact an upper surface of the third conductive pattern 330. The third output pad OP3 may include the first conductive pattern 310, the second conductive pattern 320, the third conductive pattern 330, and the fourth conductive pattern 340. For example, the third output pad OP3 may be a portion in which the first conductive pattern 310, the second conductive pattern 320, the third conductive pattern 330, and the fourth conductive pattern 340 overlap each other in a plan view.

A second conductive pattern 420 may be located on the first conductive pattern 410. The second conductive pattern 420 may fill at least a portion of the fourth through-hole. The second conductive pattern 420 may contact the upper surface of the first conductive pattern 410. A third conductive pattern 430 may be located on the second conductive pattern 420. The third conductive pattern 430 may fill at least a portion of the fourth through-hole. The third conductive pattern 430 may contact an upper surface of the second conductive pattern 420. A fourth conductive pattern 440 may be located on the third conductive pattern 430. The fourth conductive pattern 440 may fill at least a portion of the fourth through-hole. The fourth conductive pattern 440 may contact an upper surface of the third conductive pattern 430. The input pad IP may include the first conductive pattern 410, the second conductive pattern 420, the third conductive pattern 430, and the fourth conductive pattern 440. For example, the input pad IP may be a portion in which the first conductive pattern 410, the second conductive pattern 420, the third conductive pattern 430, and the fourth conductive pattern 440 overlap each other in a plan view.

The fifth insulating layer IL5 may be located on the fourth insulating layer IL4. The fifth insulating layer IL5 may not be located in (or may be omitted from, or separated from) areas where the first output pad OP1, the second output pad OP2, the third output pad OP3, and the input pad IP are located. For example, the fifth insulating layer IL5 may define a fifth through-hole overlapping the first output pad OP1, the second output pad OP2, and the third output pad OP3 in a plan view. In addition, the fifth insulating layer IL5 may define a sixth through-hole overlapping the input pad IP in a plan view. The fifth insulating layer IL5 may include an organic material, such as phenolic resin, polyacrylates resin, polyimides resin, polyamides resin, siloxane resin, epoxy resin, and/or the like. These materials may be used alone or in combination with each other.

The sixth insulating layer IL6 may be located on the fifth insulating layer IL5. The sixth insulating layer IL6 may not be located in (e.g., may be separated from) areas where the first output pad OP1, the second output pad OP2, the third output pad OP3, and the input pad IP are located. For example, the sixth insulating layer IL6 may define a seventh through-hole overlapping the first output pad OP1, the second output pad OP2, and the third output pad OP3 in a plan view. The fifth through-hole and the seventh through-hole may communicate with each other. In addition, the sixth insulating layer IL6 may define an eighth through-hole overlapping the input pad IP in a plan view. The sixth through-hole and the eighth through-hole may communicate with each other. The sixth insulating layer IL6 may include an organic material, such as phenolic resin, polyacrylates resin, polyimides resin, polyamides resin, siloxane resin, epoxy resin, and/or the like. These materials may be used alone or in combination with each other.

The first touch-insulating layer TIL1 may be located on the sixth insulating layer IL6. The first touch-insulating layer TIL1 may cover at least a portion of each of the fifth insulating layer IL5 and the sixth insulating layer IL6. For example, the first touch-insulating layer TIL1 may cover side surfaces of the fifth insulating layer IL5 exposed by, or defining, the fifth through-hole and the sixth through-hole.

In addition, the first touch-insulating layer TIL1 may cover side surfaces of the sixth insulating layer IL6 exposed by, or defining, the seventh through-hole and the eighth through-hole. The first touch-insulating layer TIL1 may also cover an upper surface of the sixth insulating layer IL6. The first touch-insulating layer TIL1 may cover at least a portion of the third conductive pattern 130, the third conductive pattern 230, the third conductive pattern 330, and the third conductive pattern 430. For example, the first touch-insulating layer TIL1 may cover a side portion of the third conductive pattern 130, the third conductive pattern 230, the third conductive pattern 330, and the third conductive pattern 430.

The first touch-insulating layer TIL1 may define a ninth through-hole overlapping the first output pad OP1 in a plan view. The fourth conductive pattern 140 may cover a side surface of the first touch-insulating layer TIL1 exposed by, or defining, the ninth through-hole. The first touch-insulating layer TIL1 may define a tenth through-hole overlapping the second output pad OP2 in a plan view. The fourth conductive pattern 240 may cover a side surface of the first touch-insulating layer TIL1 exposed by the tenth through-hole. The first touch-insulating layer TIL1 may define an eleventh through-hole overlapping the third output pad OP3 in a plan view. The fourth conductive pattern 340 may cover a side surface of the first touch-insulating layer TIL1 exposed by the eleventh through-hole. The first touch-insulating layer TIL1 may define a twelfth through-hole overlapping the input pad IP in a plan view. The fourth conductive pattern 440 may cover a side surface of the first touch-insulating layer TIL1 exposed by the twelfth through-hole. The first touch-insulating layer TIL1 may include inorganic materials, such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The second touch-insulating layer TIL2 may be located on the first touch-insulating layer TIL1. The second touch-insulating layer TIL2 may define a thirteenth through-hole overlapping the first output pad OP1 in a plan view. The fourth conductive pattern 140 may cover a side surface of the second touch-insulating layer TIL2 exposed by the thirteenth through-hole. The ninth through-hole and the thirteenth through-hole may communicate with each other. The second touch-insulating layer TIL2 may define a fourteenth through-hole overlapping the second output pad OP2 in a plan view. The fourth conductive pattern 240 may cover a side surface of the second touch-insulating layer TIL2 exposed by the fourteenth through-hole. The tenth through-hole and the fourteenth through-hole may communicate with each other. The second touch-insulating layer TIL2 may define a fifteenth through-hole overlapping the third output pad OP3 in a plan view. The fourth conductive pattern 340 may cover a side surface of the second touch-insulating layer TIL2 exposed by the fifteenth through-hole. The eleventh through-hole and the fifteenth through-hole may communicate with each other. The second touch-insulating layer TIL2 may define a sixteenth through-hole overlapping the input pad IP in a plan view. The fourth conductive pattern 440 may cover a side surface of the second touch-insulating layer TIL2 exposed by the sixteenth through-hole. The twelfth through-hole and the sixteenth through-hole may communicate with each other. The second touch-insulating layer TIL2 may include inorganic materials, such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

The first bump electrode BM1, the second bump electrode BM2, the third bump electrode BM3, and the fourth bump electrode BM4 may be located on the driving chip IC. For example, the first bump electrode BM1, the second bump electrode BM2, the third bump electrode BM3, and the fourth bump electrode BM4 may be located on a surface of the driving chip IC facing the substrate SUB. The first bump electrode BM1 may be bonded to the first output pad OP1. For example, the first bump electrode BM1 may be bonded to the first output pad OP1 through the conductive film ACF. The second bump electrode BM2 may be bonded to the second output pad OP2. For example, the second bump electrode BM2 may be bonded to the second output pad OP2 through the conductive film ACF. The third bump electrode BM3 may be bonded to the third output pad OP3. For example, the third bump electrode BM3 may be bonded to the third output pad OP3 through the conductive film ACF. The fourth bump electrode BM4 may be bonded to the input pad IP. For example, the fourth bump electrode BM4 may be bonded to the input pad IP through the conductive film ACF. As the first bump electrode BM1 is bonded to the first output pad OP1, the second bump electrode BM2 is bonded to the second output pad OP2, the third bump electrode BM3 is bonded to the third output pad OP3, and the fourth bump electrode BM4 is bonded to the input pad IP, the driving chip IC may be bonded to the substrate SUB. For example, the driving chip IC may be bonded to the first output pad OP1, the second output pad OP2, the third output pad OP3, and the input pad IP.

In one or more embodiments, the conductive film ACF may include an adhesive member AL and conductive balls BL. The adhesive member AL may include an insulating polymer. For example, the adhesive member AL may include epoxy resin, acrylic resin, and/or the like. These materials may be used alone or in combination with one another. Each of the conductive balls BL may include conductive fine particles. For example, the conductive fine particles may include a first portion (e.g., a core portion) and a second portion surrounding (or coating) the first portion. Each of the first portion and the second portion may include metal, metal oxide, metal nitride, and/or the like. These materials may be used alone or in combination with each another.

In one or more embodiments, the test circuit portion PC may include a first test pattern PC1 and a second test pattern PC2. The first test pattern PC1 may be located on the fourth insulating layer IL4. The second test pattern PC2 may be located on the fifth insulating layer IL5. The first test pattern PC1 and the second test pattern PC2 may be connected to each other through an opening formed in the fifth insulating layer IL5. However, this disclosure is not necessarily thereto, and a cross-sectional structure of the test circuit portion PC may vary depending on embodiments.

Hereinafter, a cross-sectional structure of the first groove GR1, the second groove GR2, and the third groove GR3 will be described.

In one or more embodiments, the first touch-insulating layer TIL1 may define a first hole H1. The first hole H1 may be a portion removed from an upper surface to a lower surface of the first touch-insulating layer TIL1. The second touch-insulating layer TIL2 may define a second hole H2. The second hole H2 may be a portion removed from an upper surface to a lower surface of the second touch-insulating layer TIL2. The first hole H1 and the second hole H2 may communicate with each other, thereby forming the first groove GR1. For example, the first groove GR1 may include the first hole H1 and the second hole H2.

In one or more embodiments, the first touch-insulating layer TIL1 may define a third hole H3. The third hole H3 may be a portion removed from an upper surface to a lower surface of the first touch-insulating layer TIL1. The second touch-insulating layer TIL2 may define a fourth hole H4. The fourth hole H4 may be a portion removed from an upper surface to a lower surface of the second touch-insulating layer TIL2. The third hole H3 and the fourth hole H4 may communicate with each other, thereby forming the second groove GR2. For example, the second groove GR2 may include the third hole H3 and the fourth hole H4.

In one or more embodiments, the first touch-insulating layer TIL1 may define a fifth hole H5. The fifth hole H5 may be a portion removed from an upper surface to a lower surface of the first touch-insulating layer TIL1. The second touch-insulating layer TIL2 may define a sixth hole H6. The sixth hole H6 may be a portion removed from an upper surface to a lower surface of the second touch-insulating layer TIL2. The fifth hole H5 and the sixth hole H6 may communicate with each other, thereby forming the third groove GR3. For example, the third groove GR3 may include the fifth hole H5 and the sixth hole H6.

When the driving chip IC is bonded to the substrate SUB, an impact may be applied to the first touch-insulating layer TIL1 and the second touch-insulating layer TIL2 due to pressure from the conductive balls BL. For example, an impact may be applied to the first touch-insulating layer TIL1 and the second touch-insulating layer TIL2 due to pressure of the conductive balls BL on the sixth insulating layer IL6. Accordingly, cracks may occur in the first touch-insulating layer TIL1 and the second touch-insulating layer TIL2. Impurities such as moisture may penetrate into the fifth insulating layer IL5 and the sixth insulating layer IL6 through the cracks. As a result, the fifth insulating layer IL5 and the sixth insulating layer IL6 may expand, and a delamination phenomenon may occur between the first touch-insulating layer TIL1 and the fourth insulating layer IL4. For example, a space may be formed between the first touch-insulating layer TIL1 and the fourth insulating layer IL4. In this case, impurities such as moisture may penetrate through the space into the output pads (e.g., the output pads OP of FIG. 2), the input pads (e.g., the input pads IP of FIG. 2), and/or the like. Therefore, corrosion may occur in the output pads, the input pads, and/or the like.

As the display device includes the first groove GR1 and the second groove GR2, impurities such as moisture, which may have penetrated into the space formed between the first touch-insulating layer TIL1 and the fourth insulating layer IL4, may be reduced or prevented from penetrating into the output pads. In addition, as the display device includes the third groove GR3, impurities such as moisture, which may have penetrated into the space formed between the first touch-insulating layer TIL1 and the fourth insulating layer IL4, may be reduced or prevented from penetrating into the input pads. For example, each of the first groove GR1, the second groove GR2, and the third groove GR3 may block or impede a penetration path of impurities such as moisture.

FIG. 5 is an enlarged cross-sectional view illustrating an example of area B of FIG. 3.

Referring to FIGS. 3 to 5, in one or more embodiments, as described above, the first groove GR1 may be located adjacent to the first output pad OP1. In one or more embodiments, the first groove GR1 may accommodate some of the conductive patterns included in the first output pad OP1. For example, as illustrated in FIGS. 3 and 5, the first groove GR1 may accommodate at least a portion of the fourth conductive pattern 140. However, this disclosure is not necessarily thereto, and in one or more embodiments, the first groove GR1 may accommodate at least a portion of each of the third conductive pattern 130 and the fourth conductive pattern 140. In one or more embodiments, the first groove GR1 may accommodate at least a portion of each of the second conductive pattern 120, the third conductive pattern 130, and the fourth conductive pattern 140.

In one or more embodiments, as illustrated in FIG. 3, the first groove GR1 may be spaced apart from the first conductive pattern 110 in a plan view. In one or more embodiments, the first groove GR1 may be spaced apart from the second conductive pattern 120 in a plan view. In one or more embodiments, the first groove GR1 may be spaced apart from the third conductive pattern 130 in a plan view.

As described above, the second groove GR2 may be located adjacent to the third output pad OP3. In one or more embodiments, the second groove GR2 may accommodate some of the conductive patterns included in the third output pad OP3. For example, as illustrated in FIG. 3, the second groove GR2 may accommodate at least a portion of the fourth conductive pattern 340. However, this disclosure is not necessarily thereto, and in one or more embodiments, the second groove GR2 may accommodate at least a portion of each of the third conductive pattern 330 and the fourth conductive pattern 340. In one or more embodiments, the second groove GR2 may accommodate at least a portion of each of the second conductive pattern 320, the third conductive pattern 330, and the fourth conductive pattern 340.

In one or more embodiments, as illustrated in FIG. 3, the second groove GR2 may be spaced apart from the first conductive pattern 310 in a plan view. In one or more embodiments, the second groove GR2 may be spaced apart from the second conductive pattern 320 in a plan view. In one or more embodiments, the second groove GR2 may be spaced apart from the third conductive pattern 330 in a plan view.

As described above, the third groove GR3 may be located adjacent to the input pad IP. In one or more embodiments, the third groove GR3 may accommodate some of the conductive patterns included in the input pad IP. For example, as illustrated in FIG. 4, the third groove GR3 may accommodate at least a portion of the fourth conductive pattern 440. However, this disclosure is not necessarily thereto, and in one or more embodiments, the third groove GR3 may accommodate at least a portion of each of the third conductive pattern 430 and the fourth conductive pattern 440. In one or more embodiments, the third groove GR3 may accommodate at least a portion of each of the second conductive pattern 420, the third conductive pattern 430, and the fourth conductive pattern 440.

In one or more embodiments, as illustrated in FIG. 4, the third groove GR3 may be spaced apart from the first conductive pattern 410 in a plan view. In one or more embodiments, the third groove GR3 may be spaced apart from the second conductive pattern 420 in a plan view. In one or more embodiments, the third groove GR3 may be spaced apart from the third conductive pattern 430 in a plan view.

Referring further to FIG. 2, when the driving chip IC is bonded to the substrate SUB, stress may be applied to the substrate SUB and insulating layers located on the substrate SUB. For example, as illustrated in FIG. 2, when the test circuit portion PC includes a first surface facing the second groove GR2 in a plan view, a second surface facing the third groove GR3, a third surface facing the first direction DR1, and a fourth surface facing a direction opposite to the first direction DR1, tensile stress may be concentrated on the insulating layers located around the first surface and the insulating layers located around the second surface when the driving chip IC is bonded to the substrate SUB.

Accordingly, when the second groove GR2 is located around the first surface, tensile stress may be concentrated on the second groove GR2. In this case, cracks may occur in the insulating layers located around the second groove GR2. The cracks may propagate along the fourth insulating layer IL4, the third insulating layer IL3, and/or the like, and may reach the first conductive pattern 310, the second conductive pattern 320, the third conductive pattern 330, and/or the like. Therefore, the first conductive pattern 310, the second conductive pattern 320, the third conductive pattern 330, and/or the like may be damaged.

According to one or more embodiments of the present disclosure, when the second groove GR2 is instead located adjacent to the third output pads OP3, tensile stress may not be applied to the second groove GR2 when the driving chip IC is bonded to the substrate SUB. For example, when the second groove GR2 is located adjacent to the third output pads OP3, compressive stress may be applied to the second groove GR2 when the driving chip IC is bonded to the substrate SUB. Accordingly, generation and propagation of cracks around the second groove GR2 may be reduced or prevented. For example, cracks may be reduced or prevented from being generated in the insulating layers located around the second groove GR2, and propagation of the cracks along the insulating layers may also be reduced or prevented.

When the third groove GR3 is located around the second surface, tensile stress may be concentrated on the third groove GR3. In this case, cracks may occur in insulating layers located around the third groove GR3. The cracks may propagate along the fourth insulating layer IL4, the third insulating layer IL3, and/or the like, and reach the first conductive pattern 410, the second conductive pattern 420, the third conductive pattern 430, and/or the like. Therefore, the first conductive pattern 410, the second conductive pattern 420, the third conductive pattern 430, and/or the like may be damaged.

According to one or more embodiments of the present disclosure, when the third groove GR3 is instead located adjacent to the input pads IP, tensile stress may not be applied to the third groove GR3 when the driving chip IC is bonded to the substrate SUB. For example, when the third groove GR3 is located adjacent to the input pads IP, compressive stress may be applied to the third groove GR3 when the driving chip IC is bonded to the substrate SUB. Accordingly, generation and propagation of cracks around the third groove GR3 may be reduced or prevented. For example, cracks may be reduced or prevented from being generated in the insulating layers located around the third groove GR3, and propagation of the cracks along the insulating layers may also be reduced or prevented.

According to one or more embodiments of the present disclosure, when the first groove GR1 is located adjacent to the first output pads OP1, tensile stress may not be applied to the first groove GR1 when the driving chip IC is bonded to the substrate SUB. For example, when the first groove GR1 is located adjacent to the first output pads OP1, compressive stress may be applied to the first groove GR1 when the driving chip IC is bonded to the substrate SUB. Accordingly, generation and propagation of cracks around the first groove GR1 may be reduced or prevented. For example, cracks may be reduced or prevented from being generated in the insulating layers located around the first groove GR1, and propagation of the cracks along the insulating layers may also be reduced or prevented.

As described above, the first groove GR1 may accommodate at least a portion of the fourth conductive pattern 140. The fourth conductive pattern 140 may reduce or prevent generation and propagation of cracks around the first groove GR1. For example, the fourth conductive pattern 140 may reduce or prevent cracks from being generated in the fourth insulating layer IL4 located around the first groove GR1. This may be because, when the driving chip IC is pressed onto the substrate SUB, the fourth conductive pattern 140 may reduce or prevent stress from being applied to the fourth insulating layer IL4 that is exposed through the first groove GR1.

As described above, the second groove GR2 may accommodate at least a portion of the fourth conductive pattern 340. The fourth conductive pattern 340 may reduce or prevent generation and propagation of cracks around the second groove GR2. For example, the fourth conductive pattern 340 may reduce or prevent cracks from being generated in the fourth insulating layer IL4 located around the second groove GR2. This may be because the fourth conductive pattern 340 may reduce or prevent stress from being applied to the fourth insulating layer IL4 that is exposed through the second groove GR2 if the driving chip IC is pressed onto the substrate SUB.

As described above, the third groove GR3 may accommodate at least a portion of the fourth conductive pattern 440. The fourth conductive pattern 440 may reduce or prevent generation and propagation of cracks around the third groove GR3. For example, the fourth conductive pattern 440 may reduce or prevent cracks from being generated in the fourth insulating layer IL4 located around the third groove GR3. This may be because, when the driving chip IC is pressed onto the substrate SUB, the fourth conductive pattern 440 may reduce or prevent stress from being applied to the fourth insulating layer IL4 that is exposed through the third groove GR3.

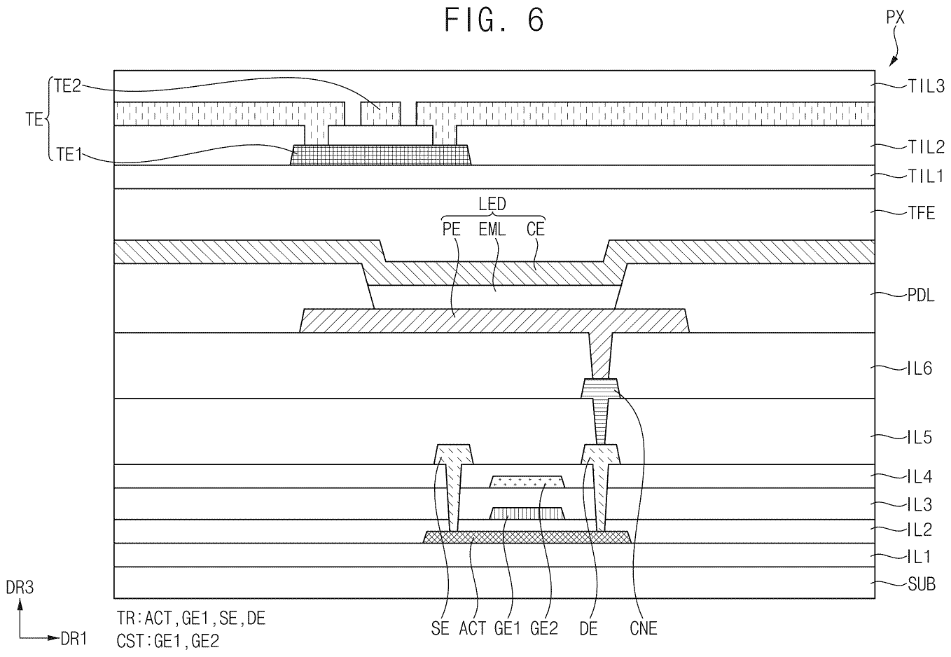

FIG. 6 is a cross-sectional view illustrating a pixel included in the display device of FIG. 1.

In describing the pixel PX illustrated in FIG. 6, same reference numerals are used for components that are substantially similar to the components described with reference to FIG. 3, and a detailed description thereof may be omitted.

Referring to FIG. 6, the pixel PX may include the substrate SUB, a transistor TR, the first insulating layer IL1, the second insulating layer IL2, the third insulating layer IL3, the fourth insulating layer IL4, the fifth insulating layer IL5, the sixth insulating layer IL6, a second gate electrode GE2, a connection electrode CNE, a light-emitting element LED, a pixel-defining layer PDL, an encapsulation layer TFE, the first touch-insulating layer TIL1, the second touch-insulating layer TIL2, a touch electrode TE, and a third touch-insulating layer TIL3.

The transistor TR may include an active pattern ACT, a first gate electrode GE1, a first contact electrode SE, and a second contact electrode DE. The capacitor CST may include the first gate electrode GE1 and the second gate electrode GE2. The light-emitting element LED may include a pixel electrode PE, a light-emitting layer EML, and a common electrode CE. The touch electrode TE may include a first touch electrode TE1 and a second touch electrode TE2.

The active pattern ACT may be located on the first insulating layer IL1. The active pattern ACT may include a first contact area, a second contact area, and a channel area positioned between the first contact area and the second contact area. The active pattern ACT may include an inorganic semiconductor (e.g., amorphous silicon, polysilicon, a metal oxide semiconductor), an organic semiconductor, and/or the like. These materials may be used alone or in combination with each other. The metal oxide semiconductor may include a binary compound (“ABₓ”), a ternary compound (“ABₓC_{y}”), a quaternary compound (“ABₓC_{y}D_{z}”), and/or the like including indium (“In”), zinc (“Zn”), gallium (“Ga”), tin (“Sn”), titanium (“Ti”), aluminum (“Al”), hafnium (“Hf”), zirconium (“Zr”), magnesium (“Mg”), and/or the like. These materials may be used alone or in combination with each other. For example, the metal oxide semiconductor may include zinc oxide (“ZnOₓ”), gallium oxide (“GaOₓ”), tin oxide (“SnOₓ”), indium oxide (“InOₓ”), indium gallium oxide (“IGO”), indium zinc oxide (“IZO”), indium tin oxide (“ITO”), indium zinc tin oxide (“IZTO”), and indium gallium zinc oxide (“IGZO”). These materials may be used alone or in combination with each other.

The second insulating layer IL2 may cover the active pattern ACT. The first gate electrode GE1 may be located on the second insulating layer IL2. The first gate electrode GE1 may overlap the channel area of the active pattern ACT in a plan view. The first gate electrode GE1 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

In one or more embodiments, the first gate electrode GE1, the first conductive patterns (e.g., the first conductive patterns 110, 210, and 310 of FIG. 3 and 410 of FIG. 4) may include substantially a same material as each other, and may be located in a same layer as each other. The third insulating layer IL3 may cover the first gate electrode GE1. The second gate electrode GE2 may be located on the third insulating layer IL3. The second gate electrode GE2 may overlap the first gate electrode GE1 in a plan view. The capacitor CST may be formed by overlapping the first gate electrode GE1 and the second gate electrode GE2 in a plan view. For example, the capacitor CST may include the first gate electrode GE1 and the second gate electrode GE2. The second gate electrode GE2 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

The fourth insulating layer IL4 may cover the second gate electrode GE2. The first contact electrode SE and the second contact electrode DE may be located on the fourth insulating layer IL4. The first contact electrode SE may be connected to the first contact area of the active pattern ACT through a contact hole penetrating (or defining through, or defined by) the second insulating layer IL2, the third insulating layer IL3, and the fourth insulating layer IL4. The second contact electrode DE may be connected to the second contact area of the active pattern ACT through a contact hole penetrating (or defining through) the second insulating layer IL2, the third insulating layer IL3, and the fourth insulating layer IL4. For example, each of the first contact electrode SE and the second contact electrode DE may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

In one or more embodiments, the first contact electrode SE, the second contact electrode DE, the second conductive patterns (e.g., the second conductive patterns 120, 220, and 320 of FIG. 3 and 420 of FIG. 4) may include substantially a same material as each other, and may be located in a same layer as each other.

The fifth insulating layer IL5 may cover the first contact electrode SE and the second contact electrode DE. The connection electrode CNE may be located on the fifth insulating layer IL5. The connection electrode CNE may be connected to the transistor TR through a contact hole penetrating (or defining through) the fifth insulating layer IL5. For example, the connection electrode CNE may be connected to the second contact electrode DE through a contact hole penetrating (or defining through) the fifth insulating layer IL5. The connection electrode CNE may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

In one or more embodiments, the connection electrode CNE, the third conductive patterns (e.g., the third conductive patterns 130, 230, and 330 of FIG. 3 and 430 of FIG. 4) may include substantially a same material as each other, and may be located in a same layer as each other.

The sixth insulating layer IL6 may cover the connection electrode CNE. The pixel electrode PE may be located on the sixth insulating layer IL6. The pixel electrode PE may be connected to the connection electrode CNE through a contact hole penetrating (or defining through) the sixth insulating layer IL6. The pixel electrode PE may include metals, alloys, metal nitrides, conductive metal oxides, transparent conductive materials, and/or the like. These materials may be used alone or in combination with each other. In one or more embodiments, the pixel electrode PE may have a stacked structure including ITO/Ag/ITO. For example, the pixel electrode PE may function as an anode of the light-emitting element LED.

The pixel-defining layer PDL may be located on the sixth insulating layer IL6. The pixel-defining layer PDL may cover a side portion of the pixel electrode PE. For example, a pixel opening may be defined in the pixel-defining layer PDL to expose a portion of an upper surface of the pixel electrode PE. In one or more embodiments, the pixel-defining layer PDL may include inorganic materials or organic materials. In one or more embodiments, the pixel-defining layer PDL may include organic materials, such as epoxy resin, siloxane resin, and/or the like. These materials may be used alone or in combination with each other. In one or more embodiments, the pixel-defining layer PDL may further include a light-blocking material containing black pigments, black dyes, and/or the like.

The light-emitting layer EML may be located on the pixel electrode PE. The light-emitting layer EML may include an organic material that emits light of a selected color. For example, the light-emitting layer EML may include an organic material that emits red light. However, the present disclosure is not necessarily thereto.

The common electrode CE may be located on the light-emitting layer EML. The common electrode CE may include metal, alloys, metal nitrides, conductive metal oxides, transparent conductive materials, and/or the like. These materials may be used alone or in combination with each other. The common electrode CE may function as a cathode of the light-emitting element LED.

The encapsulation layer TFE may be located on the common electrode CE. The encapsulation layer TFE may reduce or prevent external impurities, moisture, and/or the like from penetrating into the pixel electrode PE, the light-emitting layer EML, and the common electrode CE. The encapsulation layer TFE may include at least one inorganic layer and at least one organic layer. For example, the inorganic layer may include silicon oxide, silicon nitride, silicon oxynitride, and/or the like. These materials may be used alone or in combination with each other. The organic layer may include polymerized materials, such as polyacrylate.

The first touch-insulating layer TIL1 may be located on the encapsulation layer TFE. The first touch electrode TE1 may be located on the first touch-insulating layer TIL1. The first touch electrode TE1 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

The second touch-insulating layer TIL2 may cover the first touch electrode TE1. The second touch electrode TE2 may be located on the second touch-insulating layer TIL2. In one or more embodiments, the second touch electrode TE2 may be connected to the first touch electrode TE1 through a contact hole penetrating (or defining through) the second touch-insulating layer TIL2. The second touch electrode TE2 may include a metal, an alloy, a metal nitride, a conductive metal oxide, a transparent conductive material, and/or the like. Examples of the metal may include silver (“Ag”), molybdenum (“Mo”), aluminum (“Al”), tungsten (“W”), copper (“Cu”), nickel (“Ni”), chromium (“Cr”), titanium (“Ti”), tantalum (“Ta”), platinum (“Pt”), scandium (“Sc”), and/or the like. These materials may be used alone or in combination with each other. Examples of the conductive metal oxide may include Indium tin oxide, indium zinc oxide, and/or the like. These materials may be used alone or in combination with each other. In addition, examples of the metal nitride may include aluminum nitride (“AlNₓ”), tungsten nitride (“WNₓ”), chromium nitride (“CrNₓ”), and/or the like. These materials may be used alone or in combination with each other.

In one or more embodiments, the second touch electrode TE2, the fourth conductive patterns (e.g., the fourth conductive patterns 140, 240, and 340 of FIG. 3 and 440 of FIG. 4) may include substantially a same material as each other, and may be located in a same layer as each other.

The third touch-insulating layer TIL3 may be located on the second touch-insulating layer TIL2 to cover the second touch electrode TE2. In one or more embodiments, the third touch-insulating layer TIL3 may be located in the display area (e.g., the display area DA of FIG. 1), and may be omitted in a portion where the driving chip (e.g., the driving chip IC of FIG. 1) is located. However, the present disclosure is not necessarily thereto, and in one or more embodiments, the third touch-insulating layer TIL3 may also be located in the portion where the driving chip is located. The third touch-insulating layer TIL3 may include inorganic materials, such as silicon oxide (“SiOₓ”), silicon nitride (“SiNₓ”), silicon carbide (“SiCₓ”), silicon oxynitride (“SiOₓN_{y}”), silicon oxycarbide (“SiOₓC_{y}”), and/or the like. These materials may be used alone or in combination with each other.

Referring to FIG. 6, one or mor embodiments of the pixel PX has been described. However, the pixel PX is not limited to a structure illustrated in FIG. 6. For example, the pixel PX may include any structure that receives an electrical signal, and that emits light with a luminance corresponding to intensity of the electrical signal.

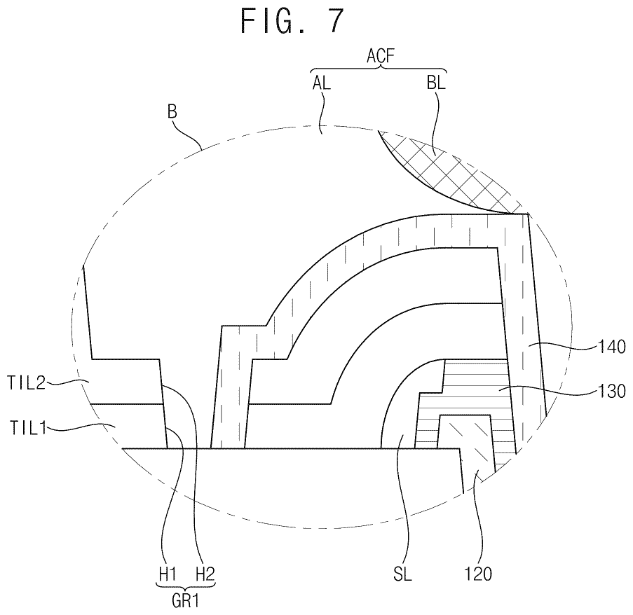

FIG. 7 is an enlarged cross-sectional view illustrating an example of area B of FIG. 3.

Components described with reference to FIG. 7 may differ only in a side insulating layer SL when compared to components described with reference to FIG. 5. Therefore, redundant explanations may be omitted or simplified.

Referring to FIG. 7, the display device (e.g., the display device DD of FIG. 1) according to embodiments may further include a side insulating layer SL. The side insulating layer SL may cover at least a portion of the third conductive pattern 130. For example, the side insulating layer SL may cover a side surface of the third conductive pattern 130. The side insulating layer SL may serve to protect the third conductive pattern 130. For example, when insulating layers (e.g., the first touch-insulating layer TIL1 of FIG. 3) and conductive patterns (e.g., the fourth conductive pattern 140 of FIG. 3) are formed by an etching process, and/or the like, the side insulating layer SL may protect the third conductive pattern 130 from being etched, thereby reducing or preventing damage to the third conductive pattern 130.

FIG. 7 may illustrate one example in which the side insulating layer SL covers the side surface of the third conductive pattern 130. However, the present disclosure is not necessarily thereto, and the side insulating layer SL may cover side surfaces of the third conductive patterns (e.g., the third conductive patterns 230 and 330 of FIGS. 3 and 430 of FIG. 4).

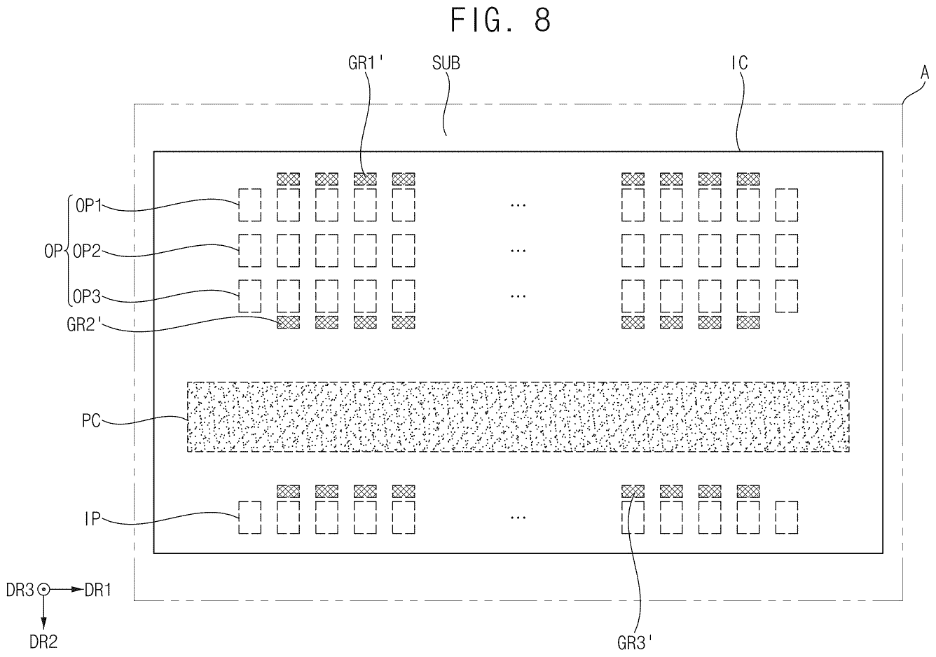

FIG. 8 is an enlarged plan view illustrating an example of area A of FIG. 1.

Components described with reference to FIG. 8 may differ only in the first groove GR1′, the second groove GR2′, and the third groove GR3′ when compared to components described with reference to FIG. 2. Therefore, redundant explanations may be omitted or simplified.

Referring to FIG. 8, the display device may include the first groove GR1′, the second groove GR2′, and the third groove GR3′. The first groove GR1′ may be located adjacent to the first output pads OP1, the second groove GR2′ may be located adjacent to the third output pads OP3, and the third groove GR3′ may be located adjacent to the input pads IP.

In one or more embodiments, the first groove GR1′ may be repeatedly arranged in an island shape. For example, the first groove GR1′ may be repeatedly arranged in an island shape along the first direction DR1. For example, the first groove GR1′ may include first grooves that repeat in an island shape, and each of the first grooves may overlap, or may be aligned with, a corresponding output pad among the first output pads OP1 in the second direction DR2.

In one or more embodiments, the second groove GR2′ may be repeatedly arranged in an island shape. For example, the second groove GR2′ may be repeatedly arranged in an island shape along the first direction DR1. For example, the second groove GR2′ may include second grooves that repeat in an island shape, and each of the second grooves may overlap, or may be aligned with, a corresponding output pad among the third output pads OP3 in the second direction DR2.

In one or more embodiments, the third groove GR3′ may be repeatedly arranged in an island shape. For example, the third groove GR3′ may be repeatedly arranged in an island shape along the first direction DR1. For example, the third groove GR3′ may include third grooves that repeat in an island shape, and each of the third grooves may overlap, or may be aligned with, a corresponding input pad among the input pads IP in the second direction DR2.

Cross-sectional structures of the first groove GR1′ and the second groove GR2′ may be substantially similar to structures of the first groove GR1 and the second groove GR2, respectively, described with reference to FIG. 3. A cross-sectional structure of the third groove GR3′ may be substantially similar to a structure of the third groove GR3 described with reference to FIG. 4.

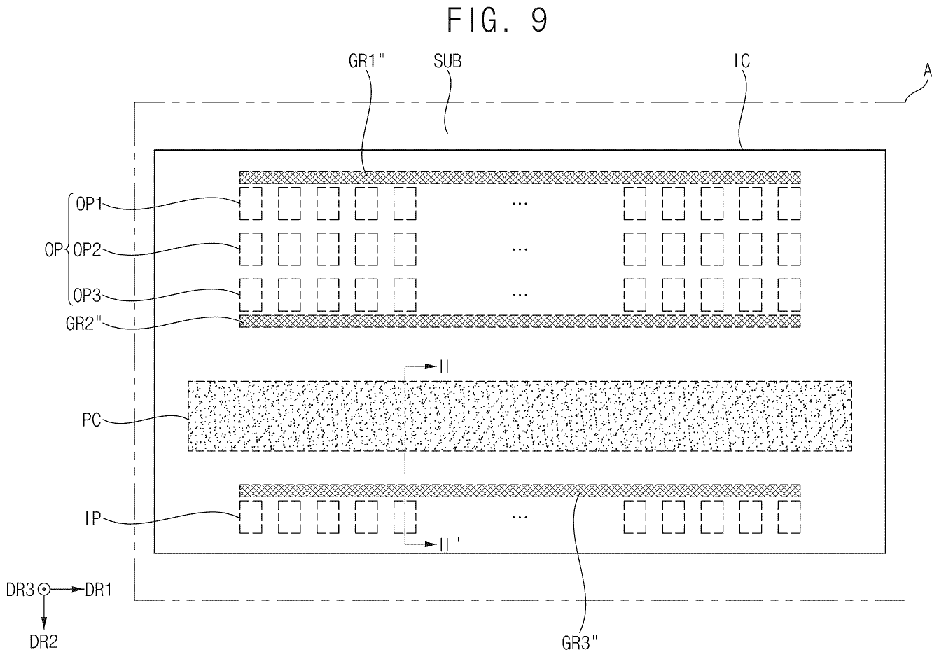

FIG. 9 is an enlarged plan view illustrating an example of area A of FIG. 1.

Components described with reference to FIG. 9 may differ only in the first groove GR1″, the second groove GR2″, and the third groove GR3″ when compared to components described with reference to FIG. 2. Therefore, redundant explanations may be omitted or simplified.

Referring to FIG. 9, the display device may include the first groove GR1″, the second groove GR2″, and the third groove GR3″. The first groove GR1″ may be located adjacent to the first output pads OP1, the second groove GR2″ may be located adjacent to the third output pads OP3, and the third groove GR3″ may be located adjacent to the input pads IP.

In one or more embodiments, the first groove GR1″ may overlap the output pads OP in the second direction DR2. For example, each of the output pads OP may overlap, or may be aligned with, a respective portion of the first groove GR1″ in the second direction DR2. For example, when the output pads OP are arranged in m rows (where m is a natural number) and n columns (where n is a natural number), the first groove GR1″ may extend in the first direction DR1 from a portion where output pads of the first column are located to a portion where output pads of the n-th column are located.

In one or more embodiments, the second groove GR2″ may overlap the output pads OP in the second direction DR2. For example, each of the output pads OP may overlap some portion of the second groove GR2″ in the second direction DR2. For example, the second groove GR2″ may extend in the first direction DR1 from a portion where output pads of the first column are located to the portion where output pads of the n-th column are located.

In one or more embodiments, the third groove GR3″ may overlap the input pads IP in the second direction DR2. For example, each of the input pads IP may overlap the third groove GR3″ in the second direction DR2. For example, the third groove GR3″ may extend in the first direction DR1 from a portion where output pads of the first column are located to a portion where the output pads of the n-th column are located.

Cross-sectional structures of the first groove GR1′ and the second groove GR2′ may be substantially similar to structures of the first groove GR1 and the second groove GR2, respectively, described with reference to FIG. 3. A cross-sectional structure of the third groove GR3″ may be substantially same as a structure of the third groove GR3 described with reference to FIG. 4.

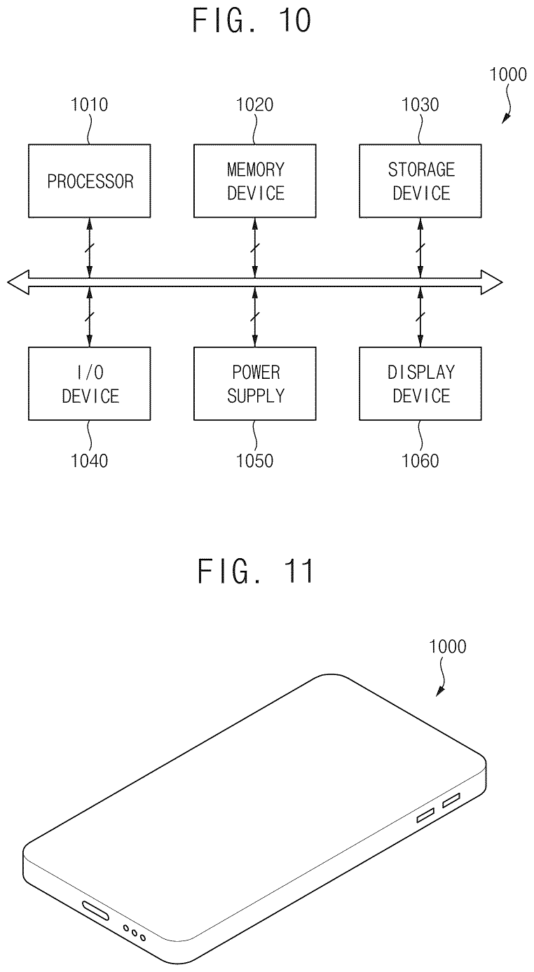

FIG. 10 is a block diagram illustrating an electronic device according to embodiments. FIG. 11 is a diagram illustrating an example in which the electronic device of FIG. 10 is implemented as a smartphone.

Referring to FIGS. 10 and 11, an electronic device 1000 may include a processor 1010, a memory device 1020, a storage device 1030, an input/output device 1040, a power supply 1050, and a display device 1060. In this case, the display device 1060 may be the display device DD of FIG. 1. In addition, the electronic device 1000 may further include multiple ports that allow communication with devices, such as a video card, sound card, memory card, USB devices, or other systems.

In one or more embodiments, as illustrated in FIG. 11, the electronic device 1000 may be implemented as a smartphone. However, this is merely an example, and the electronic device 1000 may be implemented as various devices depending on embodiments. For example, the electronic device 1000 may be implemented as a mobile phones, video phones, smart pads, smart watches, tablet PCs, vehicle navigation systems, computer monitors, laptops, head-mounted display devices, and/or the like.

The processor 1010 may be a microprocessor, central processing unit (“CPU”), application processor, and/or the like. The processor 1010 may be connected to other components through an address bus, control bus, data bus, and/or the like. In one or more embodiments, the processor 1010 may also be connected to an expansion bus, such as a peripheral component interconnect (“PCI”) bus.

The memory device 1020 may store data suitable for an operation of the electronic device 1000. For example, the memory device 1020 may include non-volatile memory devices, such as erasable programmable read-only memory (“EPROM”), electrically erasable programmable read-only memory (“EEPROM”), flash memory devices, phase change random access memory (“PRAM”), resistance random access memory (“RRAM”), nano floating gate memory (“NFGM”), polymer random access memory (“PoRAM”), magnetic random access memory (“MRAM”), ferroelectric random access memory (“FRAM”), and/or volatile memory devices, such as dynamic random access memory (“DRAM”), static random access memory (“SRAM”), mobile DRAM, and/or the like.

The storage device 1030 may include a solid state drive (“SSD”), hard disk drive (“HDD”), CD-ROM, and/or the like.

The input/output device 1040 may include input means, such as a keyboard, keypad, touchpad, touchscreen, mouse, output means, such as a speaker, printer, and/or the like. In one or more embodiments, the display device 1060 may be included in the input/output device 1040.

The power supply 1050 may supply power suitable for an operation of the electronic device 1000. For example, the power supply 1050 may supply power for the operation of the display device 1060.

The display device 1060 may be connected to other components through buses or other communication links.

The present disclosure can be applied to various display devices. For example, the present disclosure is applicable to various display devices, such as display devices for vehicles, ships and aircraft, portable communication devices, display devices for exhibition or information transmission, medical display devices, and the like.

The foregoing is illustrative of embodiments and is not to be construed as limiting thereof. Although a few embodiments have been described, those skilled in the art will readily appreciate that many modifications are possible in the embodiments without materially departing from the aspects of the present disclosure. Accordingly, all such modifications are intended to be included within the scope of the present disclosure as defined in the claims. Therefore, it is to be understood that the foregoing is illustrative of various embodiments and is not to be construed as limited to the specific embodiments disclosed, and that modifications to the disclosed embodiments, as well as other embodiments, are intended to be included within the scope of the appended claims.

What is claimed is:

1. A display device comprising:
a substrate comprising a display area, and a non-display area adjacent to the display area;
a light-emitting element in the display area above the substrate;
output pads in the non-display area above the substrate;
input pads in the non-display area above the substrate, and spaced apart from the output pads in a plan view;
a first groove adjacent to the output pads; and
a driving chip bonded to the output pads and the input pads.

2. The display device of claim 1, wherein the first groove is adjacent to ones of the output pads at an outermost position among the output pads.

3. The display device of claim 2, wherein the ones of the output pads at the outermost position comprise stacked conductive patterns, and
wherein the first groove accommodates one or more of the conductive patterns.

4. The display device of claim 2, wherein the ones of the output pads at the outermost position comprise a first conductive pattern, a second conductive pattern above the first conductive pattern, a third conductive pattern above the second conductive pattern, and a fourth conductive pattern above the third conductive pattern, and
wherein the first groove accommodates at least a portion of the fourth conductive pattern.

5. The display device of claim 4, wherein the first groove is spaced apart from the third conductive pattern in a plan view.

6. The display device of claim 4, further comprising:
a first touch electrode above the light-emitting element; and
a second touch electrode above the first touch electrode,
wherein the fourth conductive pattern and the second touch electrode are in a same layer.

7. The display device of claim 1, wherein the output pads are in a first row, in a second row, and in a third row, and
wherein the first groove is adjacent to ones of the output pads in the first row.

8. The display device of claim 7, further comprising a second groove adjacent to others of the output pads in the third row.

9. The display device of claim 8, wherein the others of the output pads in the third row comprise stacked conductive patterns, and
wherein the second groove accommodates one or more of the conductive patterns.

10. The display device of claim 8, wherein the others of the output pads in the third row comprise a first conductive pattern, a second conductive pattern above the first conductive pattern, a third conductive pattern above the second conductive pattern, and a fourth conductive pattern above the third conductive pattern, and
wherein the second groove accommodates at least a portion of the fourth conductive pattern, and is spaced apart from the third conductive pattern in a plan view.

11. The display device of claim 1, further comprising a third groove adjacent to the input pads, the input pads comprising stacked conductive patterns,
wherein the third groove accommodates one or more of the conductive patterns.

12. The display device of claim 1, wherein the first groove is repeatedly arranged in an island shape.

13. A display device comprising:
a substrate comprising a display area, and a non-display area adjacent to the display area;
a light-emitting element in the display area above the substrate;
output pads in the non-display area above the substrate;
input pads in the non-display area above the substrate, and spaced apart from the output pads in a plan view;
a first groove adjacent to the input pads; and
a driving chip bonded to the output pads and the input pads.

14. The display device of claim 13, wherein the input pads comprises stacked conductive patterns, and
wherein the first groove accommodates one or more of the conductive patterns.

15. The display device of claim 13, wherein the input pads comprise a first conductive pattern, a second conductive pattern above the first conductive pattern, a third conductive pattern above the second conductive pattern, and a fourth conductive pattern above the third conductive pattern, and
wherein the first groove accommodates at least a portion of the fourth conductive pattern.

16. The display device of claim 15, wherein the first groove is spaced apart from the third conductive pattern in a plan view.

17. The display device of claim 15, further comprising:
a first touch electrode above the light-emitting element; and
a second touch electrode above the first touch electrode,
wherein the fourth conductive pattern and the second touch electrode are in a same layer.

18. An electronic device comprising:
a substrate comprising a display area, and a non-display area adjacent to the display area;
a light-emitting element in the display area above the substrate;
output pads in the non-display area above the substrate;
input pads in the non-display area above the substrate, and spaced apart from the output pads in a plan view;
a first groove adjacent to the output pads;
a driving chip bonded to the output pads and the input pads; and
a memory device configured to store data information.

19. The electronic device of claim 18, wherein the first groove is adjacent to ones of the output pads at an outermost position among the output pads.

20. The electronic device of claim 19, wherein the ones of the output pads at the outermost position comprises stacked conductive patterns, and
wherein the first groove accommodates one or more of the conductive patterns.
